(19) United States
(12) Patent Application Publication
(10) Pub. No.: US 2026/0013214 A1
(43) Pub. Date: Jan. 8, 2026

(54) SEMICONDUCTOR DEVICE

(71) Applicant: Nuvoton Technology Corporation Japan, Kyoto (JP)

(72) Inventors: Hironao NAKAMURA, Kyoto (JP); Ryosuke OKAWA, Kyoto (JP); Eiji YASUDA, Kyoto (JP)

(21) Appl. No.: 19/331,470

(22) Filed: Sep. 17, 2025

Related U.S. Application Data
(63) Continuation of application No. PCT/JP2024/017773, filed on May 14, 2024.
(60) Provisional application No. 63/510,507, filed on Jun. 27, 2023.
(60) Provisional application No. 63/515,265, filed on Jul. 24, 2023.

(51) Int. Cl. H10D 84/83; H01L 23/00; H10D 62/60; H10D 64/23

(52) U.S. Cl. CPC H10D 84/83125; H01L 24/05; H10D 62/60; H10D 64/2523; H10D 84/837; H01L 2224/05567

(57) ABSTRACT

A semiconductor device includes: a semiconductor layer that includes a semiconductor substrate on a back face side and is divided into a first region, a second region, and a third region that do not overlap each other and are not dispersedly disposed in a plan view of the semiconductor device; a first vertical metal-oxide-semiconductor (MOS) transistor provided in the first region of the semiconductor layer; a second vertical MOS transistor provided in the second region of the semiconductor layer; and a drain pad connected to the semiconductor substrate, at a position within the third region in the plan view of the semiconductor device. In the plan view of the semiconductor device, the third region is interposed between the first region and the second region. In the plan view of the semiconductor device, an area of the first region is larger than an area of the second region.

### CROSS REFERENCE TO RELATED APPLICATIONS

This is a continuation application of PCT International Patent Application No. PCT/JP2024/017773 filed on May 14, 2024, designating the United States of America, which is based on and claims priority of U.S. Provisional Patent Application No. 63/510,507 filed on Jun. 27, 2023 and U.S. Provisional Patent Application No. 63/515,265 filed on Jul. 24, 2023. The entire disclosures of the above-identified applications, including the specifications, drawings and claims are incorporated herein by reference in their entirety.

### FIELD

The present disclosure relates to semiconductor devices and, more specifically, to chip-size-package type semiconductor devices.

### BACKGROUND

At least one vertical MOS transistor can be used in an electrical circuit that integrates two paths that differ in current value in specification into one path.

### CITATION LIST

### Patent Literature

PTL 1: Japanese Patent No. 7475569

### SUMMARY

### Technical Problem

There has been a demand for downsizing a circuit including at least one vertical MOS transistor.

### Solution to Problem

In order to solve the above problem, a semiconductor device according to one aspect of the present disclosure is a semiconductor device that is a facedown mountable, chip-size-package type semiconductor device, the semiconductor device comprising: a semiconductor layer that includes a semiconductor substrate on a back face side and is divided into a first region, a second region, and a third region that do not overlap each other and are not dispersedly disposed in a plan view of the semiconductor device; a first vertical metal-oxide-semiconductor (MOS) transistor an entirety of which is provided in the first region of the semiconductor layer; a second vertical MOS transistor an entirety of which is provided in the second region of the semiconductor layer; and a metal layer that is provided in contact with the back face side of the semiconductor layer, wherein the semiconductor substrate is a common drain region of the first vertical MOS transistor and the second vertical MOS transistor, in the plan view, a first source pad and a first gate pad of the first vertical MOS transistor are provided at positions within the first region, in the plan view, a second source pad and a second gate pad of the second vertical MOS transistor are provided at positions within the second region, in the plan view, a drain pad that is connected to the common drain region is provided at a position within the third region, in the plan view, the first region and the second region are disposed with the third region interposed therebetween, in the plan view, the third region is adjacent to the first region and the second region, and in the plan view, an area of the first region is larger than an area of the second region.

### Advantageous Effects

It is possible to decrease an area required by a circuit that integrates, for example, two conductive paths that differ in current value in specification into one conductive path more than ever before, by applying the semiconductor device including the above two vertical MOS transistors to the circuit.

Accordingly, the semiconductor device thus configured makes it possible to downsize the circuit including the at least one vertical MOS transistor.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional schematic diagram showing an example of the structure of a semiconductor device according to an embodiment.

FIG. 2A is a planar schematic diagram showing an example of the structure of the semiconductor device according to the embodiment.

FIG. 2B is a planar schematic diagram showing an example of the structure of the semiconductor device according to the embodiment.

FIG. 3 is a cross-sectional schematic diagram showing an example of the structure of a semiconductor device according to a variation of the embodiment.

FIG. 4A is a planar schematic diagram showing an approximate single unit of a first transistor according to the embodiment.

FIG. 4B is a perspective schematic diagram showing the approximate single unit of the first transistor according to the embodiment.

FIG. 5A is a cross-sectional schematic diagram showing a first conductive path of the semiconductor device according to the embodiment.

FIG. 5B is a cross-sectional schematic diagram showing a second conductive path of the semiconductor device according to the embodiment.

FIG. 6 is a circuit diagram showing an example of using the semiconductor device according to the embodiment.

FIG. 7 is a circuit diagram showing an example of using a semiconductor device according to a comparative example.

FIG. 8A is a planar schematic diagram showing an example of the structure of a transistor according to the comparative example.

FIG. 8B is a planar schematic diagram showing an example of the structure of the transistor according to the comparative example.

FIG. 9A is a planar schematic diagram showing an example of the structure of the transistor according to the comparative example.

FIG. 9B is a planar schematic diagram showing an example of the structure of the transistor according to the comparative example.

FIG. 10 is a planar schematic diagram showing an example of the structure of a transistor according to a variation of the embodiment.

FIG. 11 is a planar schematic diagram showing an example of the structure of the transistor according to a variation of the embodiment.

FIG. 12A is a planar schematic diagram showing an example of the structure of the transistor according to a variation of the embodiment.

FIG. 12B is a planar schematic diagram showing an example of the structure of the transistor according to the variation of the embodiment.

FIG. 13 is a planar schematic diagram showing a drain contact region of the semiconductor device according to the embodiment.

FIG. 14 is a graph showing a relation between a position of the drain contact region of the semiconductor device according to the embodiment and a conductive resistance in each of the first conductive path and the second conductive path.

### DESCRIPTION OF EMBODIMENT

The embodiment described below shows a specific example of the present disclosure. Numerical values, shapes, materials, constituent elements, the arrangement and connection of the constituent elements, etc. shown in the following embodiment are mere examples, and are not intended to limit the scope of the present disclosure.

In the present disclosure, the terminology “A and B are electrically connected” includes configurations in which A and B are directly connected via wiring, configurations in which A and B are directly connected without wiring, and configurations in which A and B are indirectly connected via a resistance component (resistance element, resistance wiring).

### Embodiment

### [1. Structure of Semiconductor Device]

Hereinafter, the structure of a semiconductor device according to an embodiment is described. The semiconductor device according to the embodiment is a facedown mountable, chip-size-package (CSP) type semiconductor device that includes a dual configuration in which two vertical metal-oxide-semiconductor (MOS) transistors are provided in a semiconductor substrate. The above two vertical MOS transistors are power transistors and what is called trench MOS field-effect transistors (FETs).

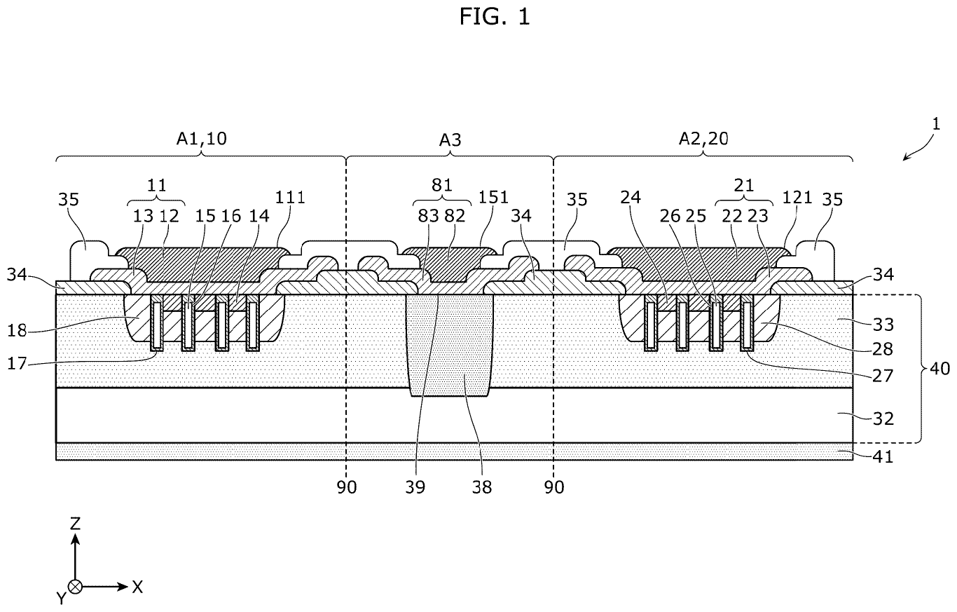

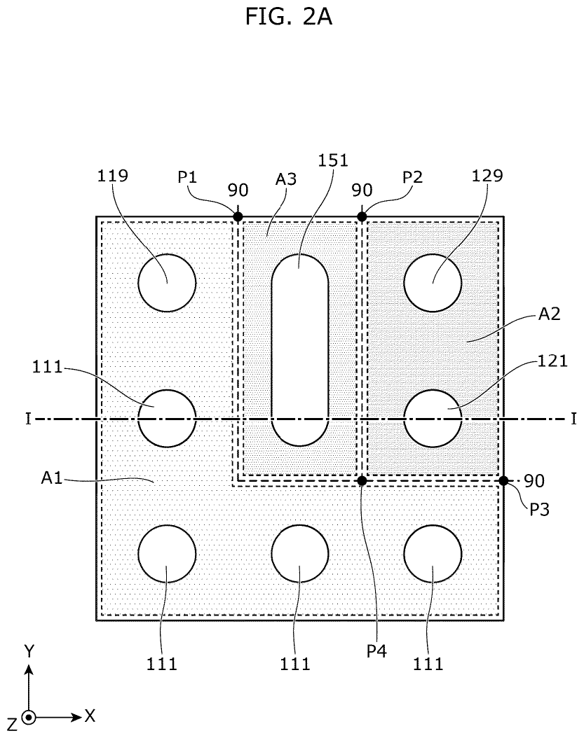

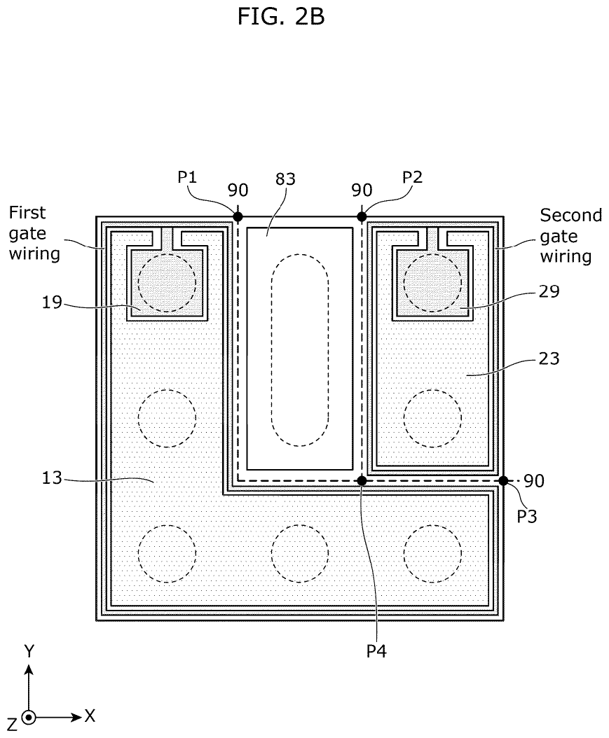

FIG. 1 is a cross-sectional schematic diagram showing an example of the structure of semiconductor device 1 according to the embodiment. FIG. 2A and FIG. 2B each are a planar schematic diagram showing an example of the structure of semiconductor device 1 according to the embodiment. The size and shape of semiconductor device 1 in FIG. 2A and FIG. 2B are an example. In addition, the size, shape, and arrangement of pads and electrodes are also an example.

FIG. 1 shows a section when semiconductor device 1 is cut along line I-I in FIG. 2A.

As shown in FIG. 1, semiconductor device 1 includes semiconductor substrate 32, metal layer 41, and low-concentration impurity layer 33 provided on semiconductor substrate 32. In the present disclosure, semiconductor substrate 32 and low-concentration impurity layer 33 are collectively referred to as semiconductor layer 40.

Semiconductor substrate 32 is disposed on a back face side of semiconductor layer 40 and includes silicon of a first conductivity type that contains impurities having a first concentration. Semiconductor layer 40 includes low-concentration impurity layer 33 of the first conductivity type that is provided in contact with semiconductor substrate 32 and includes impurities having a second concentration lower than the first concentration. Low-concentration impurity layer 33 is provided on semiconductor substrate 32 by, for example, epitaxial growth.

As shown in FIG. 1 and FIG. 2A, semiconductor device 1 includes: first vertical MOS transistor 10 (hereinafter also referred to as “transistor 10”) the entirety of which is provided in first region A1 of semiconductor layer 40; and second vertical MOS transistor 20 (hereinafter also referred to as “transistor 20”) the entirety of which is provided in second region A2 of semiconductor layer 40.

That the entirety of transistor 10 is provided in first region A1 means that, in a plan view, all elements included in transistor 10 are located within first region A1 and are not located in a region other than first region A1. Likewise, that the entirety of transistor 20 is provided in second region A2 means that, in the plan view, all elements included in transistor 20 are located within second region A2 and are not located in a region other than second region A2.

As shown in FIG. 2A, in the plan view, a front face side of semiconductor layer 40 is divided into first region A1, second region A2, and third region A3 that do not overlap each other and each of which is not dispersedly disposed. Here, that each of first region A1, second region A2, and third region A3 is not dispersedly disposed means that each of first region A1, second region A2, and third region A3 does not have an enclave. In FIG. 2A, virtual boundary lines 90 that separate first region A1, second region A2, and third region A3 are indicated by dashed lines. Although the dashed lines indicating boundary lines 90 are extended to the outside of semiconductor layer 40 for the sake of clarity, actual boundary lines 90 end at the outer periphery of semiconductor layer 40 in the plan view. (In FIG. 2A and FIG. 2B, for descriptive purposes, the ends of boundary lines 90 are indicated by P1, P2, and P3.) Boundary lines 90 are described later.

It should be noted that, in FIG. 2A, dashed lines indicating first region A1, second region A2, and third region A3 are not caused to strictly coincide with the outer periphery of semiconductor layer 40 and boundary lines 90 for the sake of clarity and are shown on the inside of the outer periphery of semiconductor layer 40 and boundary lines 90 with slight margins therebetween. However, the outer periphery of first region A1, the outer periphery of second region A2, and the outer periphery of third region A3 substantially coincide with the outer periphery of semiconductor layer 40 and boundary lines 90.

Metal layer 41 is provided in contact with the back face side of semiconductor layer 40 and may include, as a non-limiting example, silver (Ag) or copper (Cu). It should be noted that metal layer 41 may include a trace amount of a chemical element other than metal mixed in as impurities in a manufacturing process for a metal material.

As shown in FIG. 1 and FIG. 2A, first body region 18 of a second conductivity type different from the first conductivity type is provided in first region A1 of low-concentration impurity layer 33. First source region 14 of the first conductivity type is provided in first body region 18.

Moreover, a plurality of first gate trenches 17 that penetrate first source region 14 and first body region 18 from a top face of semiconductor layer 40 to a depth that reaches a portion of low-concentration impurity layer 33 are provided in first region A1. Furthermore, first gate conductor 15 is provided on first gate insulating film 16 inside each of the plurality of first gate trenches 17. First gate conductor 15 is an embedded gate electrode embedded inside semiconductor layer 40. First gate conductor 15 is electrically connected to first gate electrode 19 via first gate wiring (refer to FIG. 2B).

First source electrode 11 includes portion 12 and portion 13. Portion 12 is connected to first source region 14 and first body region 18 via portion 13.

Portion 12 of first source electrode 11 is a layer joined with solder at the time of reflow in facedown mounting and may include, as a non-limiting example, a metal material including at least one of nickel, titanium, tungsten, or palladium. The surface of portion 12 may be plated with, for example, gold. Portion 13 of first source electrode 11 is a layer that connects portion 12 and semiconductor layer 40, and may include, as a non-limiting example, a metal material including at least one of aluminum, copper, gold, or silver.

Similarly, second body region 28 of the second conductivity type different from the first conductivity type is provided in second region A2 of low-concentration impurity layer 33. Second source region 24 of the first conductivity type is provided in second body region 28.

Moreover, a plurality of second gate trenches 27 that penetrate second source region 24 and second body region 28 from the top face of semiconductor layer 40 to a depth that reaches a portion of low-concentration impurity layer 33 are provided in second region A2. Furthermore, second gate conductor 25 is provided on second gate insulating film 26 inside each of the plurality of second gate trenches 27. Second gate conductor 25 is an embedded gate electrode embedded inside semiconductor layer 40. Second gate conductor 25 is electrically connected to second gate electrode 29 via second gate wiring (refer to FIG. 2B).

Second source electrode 21 includes portion 22 and portion 23. Portion 22 is connected to second source region 24 and second body region 28 via portion 23.

Portion 22 of second source electrode 21 is a layer joined with solder at the time of reflow in facedown mounting and may include, as a non-limiting example, a metal material including at least one of nickel, titanium, tungsten, or palladium. The surface of portion 22 may be plated with, for example, gold.

Portion 23 of second source electrode 21 is a layer that connects portion 22 and semiconductor layer 40, and may include, as a non-limiting example, a metal material including at least one of aluminum, copper, gold, or silver.

FIG. 2B shows a state of semiconductor device 1 according to the embodiment immediately after portion 13 of first source electrode 11, first gate electrode 19, the first gate wiring, portion 23 of second source electrode 21, second gate electrode 29, the second gate wiring, and portion 83 of frontside drain electrode 81 to be described later are provided on the front face side of semiconductor layer 40. In FIG. 2B, for the sake of clarity, pads that cannot be seen at this moment are indicated by dashed lines.

As shown in FIG. 1, first body region 18 is covered with interlayer insulating layer 34 including openings, and portion 13 of first source electrode 11 is connected to first source region 14 via the openings of interlayer insulating layer 34. Interlayer insulating layer 34 and portion 13 of first source electrode 11 are covered with passivation layer 35 including openings, and portion 12 is connected to portion 13 of first source electrode 11 via the openings of passivation layer 35.

Likewise, second body region 28 is covered with interlayer insulating layer 34 including openings, and portion 23 of second source electrode 21 is connected to second source region 24 via the openings of interlayer insulating layer 34. Interlayer insulating layer 34 and portion 23 of second source electrode 21 are covered with passivation layer 35 including openings, and portion 22 is connected to portion 23 of second source electrode 21 via the openings of passivation layer 35.

Accordingly, as is also clear from FIG. 2B, first source pad 111 and second source pad 121 refer to a region in which first source electrode 11 is partially exposed to the surface of semiconductor device 1 and a region in which second source electrode 21 is partially exposed to the surface of semiconductor device 1, respectively, that is, terminal portions. Similarly, first gate pad 119 and second gate pad 129 refer to a region in which first gate electrode 19 is partially exposed to the surface of semiconductor device 1 and a region in which second gate electrode 29 is partially exposed to the surface of semiconductor device 1, respectively, that is, terminal portions.

The number of first source pads 111 and the number of second source pads 121 are not necessarily limited to the respective numbers exemplified in FIG. 2A. Moreover, the shapes of first source pad 111 and second source pad 121 are not necessarily limited to the respective circular shapes exemplified in FIG. 2A, and may be, for example, rectangular shapes or obround shapes. Furthermore, the positions of first source pad 111 and second source pad 121 are not limited to the respective positions exemplified in FIG. 2A.

The number of first gate pads 119 and the number of second gate pads 129 are not necessarily limited to the respective numbers exemplified in FIG. 2A, and may be at least two. Moreover, the shapes of first gate pad 119 and second gate pad 129 are not limited to the respective circular shapes exemplified in FIG. 2A, and may be, for example, rectangular shapes or obround shapes.

The above-described configurations of transistor 10 and transistor 20 allow semiconductor substrate 32 and an area of low-concentration impurity layer 33 in the proximity of an area immediately above semiconductor substrate 32 to be a common drain region having a first drain region of transistor 10 and a second drain region of transistor 20 in common.

Metal layer 41 is a common drain electrode (hereinafter also referred to as backside drain electrode 41) having a first drain electrode of transistor 10 and a second drain electrode of transistor 20 in common.

As shown in FIG. 1, drain lead-out region 38 that leads out a current from the common drain region (semiconductor substrate 32) and backside drain electrode 41 to the front face side of semiconductor layer 40 is provided in third region A3 of semiconductor layer 40. Drain lead-out region 38 is of the first conductivity type and includes impurities having a concentration higher than the first concentration of semiconductor substrate 32. Drain lead-out region 38 is provided at a depth that reaches a portion of semiconductor substrate 32 from the top face of semiconductor layer 40.

On the front face side of semiconductor layer 40, frontside drain electrode 81 that is connected to drain lead-out region 38 is provided at a position within third region A3 in the plan view. The term “frontside” is used to distinguish between frontside drain electrode 81 and backside drain electrode 41 both of which are drain electrodes.

Frontside drain electrode 81 includes portion 82 and portion 83. Portion 82 is connected to at least one of low-concentration impurity layer 33 or drain lead-out region 38 via portion 83.

Portion 82 of frontside drain electrode 81 is a layer joined with solder at the time of reflow in facedown mounting and may include, as a non-limiting example, a metal material including at least one of nickel, titanium, tungsten, or palladium. The surface of portion 82 may be plated with, for example, gold.

Portion 83 of frontside drain electrode 81 is a layer that connects portion 82 and semiconductor layer 40, and may include, as a non-limiting example, a metal material including at least one of aluminum, copper, gold, or silver.

Drain lead-out region 38 is covered with interlayer insulating layer 34 including openings, and portion 83 of frontside drain electrode 81 is connected to drain lead-out region 38 via the openings of interlayer insulating layer 34. Interlayer insulating layer 34 and portion 83 of frontside drain electrode 81 are covered with passivation layer 35 including openings, and portion 82 is connected to portion 83 of frontside drain electrode 81 via the openings of passivation layer 35.

Accordingly, as shown in FIG. 2B, drain pad 151 refers to a region in which frontside drain electrode 81 is partially exposed to the surface of semiconductor device 1, that is, a terminal portion.

The number of drain pads 151 is not necessarily limited to the number exemplified in FIG. 2A. Moreover, the shape of drain pad 151 is not necessarily limited to the obround shape exemplified in FIG. 2A, and may be, for example, a rectangular shape or a circular shape.

Although the center of drain pad 151 and the center of third region A3 coincide in the example shown in FIG. 2A, the advantageous effects of the present disclosure can be safely achieved even when the center of drain pad 151 and the center of third region A3 do not coincide.

It should be noted that the center of a shape in the plan view is defined as follows in the present disclosure. The center of a circular shape such as first source pad 111 and first gate pad 119 in FIG. 2A refers to the center thereof. The center of a rectangular shape such as third region A3 refers to the intersection point of the diagonals thereof. The center of an obround shape such as drain pad 151 refers to the intersection point of a line-symmetric axis extending in the longitudinal direction of the obround shape and a line-symmetric axis extending in the width direction of the obround shape.

A portion in which drain lead-out region 38 and portion 83 of frontside drain electrode 81 are in contact with each other is referred to as drain contact region 39. Drain contact region 39 is an overlapping portion between a region in which drain lead-out region 38 is exposed to the front face side of semiconductor layer 40 and an opening region of interlayer insulating layer 34 in the plan view. In the case of the example shown in FIG. 1, since the width of drain lead-out region 38 is greater than the width of the opening region of interlayer insulating layer 34 (the area of drain lead-out region 38 that is exposed to the front face side of semiconductor layer 40 is greater than an opening area of interlayer insulating layer 34 in the plan view), drain contact region 39 coincides with the opening region of interlayer insulating layer 34 in the plan view.

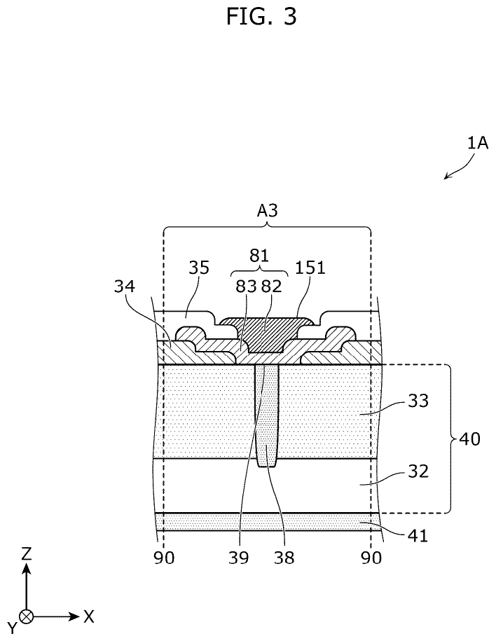

FIG. 3 is a cross-sectional schematic diagram showing a portion cut off from semiconductor device 1A according to Variation 1 obtained by changing only the shape of drain lead-out region 38 of semiconductor device 1 according to the embodiment. As shown in FIG. 3, although the width of drain lead-out region 38 may be less than an opening width of interlayer insulating layer 34, drain contact region 39 in such a case coincides with a region in which drain lead-out region 38 is exposed to the front face side of semiconductor layer 40 in the plan view.

In either case, drain contact region 39 in the plan view may have a large area to reduce a conductive resistance. Typically, in the plan view, the area of portion 83 of frontside drain electrode 81 that is in contact with semiconductor layer 40 in third region A3 (the area of the opening region of interlayer insulating layer 34) and the area of drain lead-out region 38 that is exposed to the front face side of semiconductor layer 40 may be substantially equally large regardless of variations in size.

As shown in FIG. 2A, first region A1 and second region A2 are disposed with third region A3 interposed therebetween. In the embodiment, that third region A3 is interposed between first region A1 and second region A2 means that first region A1 and third region A3 are adjacent to each other with no other region interposed therebetween, and further means that second region A2 and third region A3 are adjacent to each other with no other region interposed therebetween. Accordingly, in the plan view of semiconductor layer 40, third region A3 is adjacent to both first region A1 and second region A2.

That a region is adjacent to another region in a plan view is similar in the sense that the region is opposite to the other region, and means that the outer peripheries of the region and the other region coincide on boundary line 90 located therebetween. Hereinafter, the length of boundary line 90 may be referred to as a boundary length.

As shown in FIG. 2B, boundary line 90 between first region A1 and third region A3 may be viewed as a virtual line tracing the central position of a space between portion 13 of first source electrode 11 and portion 83 of frontside drain electrode 81. Moreover, boundary line 90 may be viewed as the space itself having a limited width. Even when boundary line 90 is the space, the space can be recognized as a line by appearance to the naked eye or with low magnification. Boundary line 90 between first region A1 and third region A3 is the dashed line from P1 to P4 in the examples shown in FIG. 2A and FIG. 2B.

Likewise, boundary line 90 between second region A2 and third region A3 may be viewed as a virtual line tracing the central position of a space between portion 23 of second source electrode 21 and portion 83 of frontside drain electrode 81. Moreover, boundary line 90 may be viewed as the space itself having a limited width. Boundary line 90 between second region A2 and third region A3 is the dashed line from P2 to P4 in the examples shown in FIG. 2A and FIG. 2B.

As shown in FIG. 2B, when first region A1 and second region A2 are adjacent to each other, boundary line 90 therebetween may be viewed as a virtual line tracing the central position of a space between portion 13 of first source electrode 11 and portion 23 of second source electrode 21. Moreover, boundary line 90 may be viewed as the space itself having a limited width. Boundary line 90 between first region A1 and second region A2 is the dashed line from P4 to P3 in the examples shown in FIG. 2A and FIG. 2B.

As shown in FIG. 2A and FIG. 2B, area a1 of first region A1 in the plan view is greater than area a2 of second region A2 in the plan view (a1>a2). By the same token, first region A1 and second region A2 do not divide in half a remaining area obtained by removing third region A3 from semiconductor layer 40 in the plan view (a1≠a2). Accordingly, the length of boundary line 90 between first region A1 and third region A3 the boundary length, the length from P1 to P4) is greater than the length of boundary line 90 between second region A2 and third region A3 (the boundary length, the length from P2 to P4).

In the examples of the embodiment shown in FIG. 2A and FIG. 2B, in the plan view, first region A1 is disposed to have the outer periphery of first region A1 partially coinciding with four sides of semiconductor layer 40. In contrast, second region A2 is disposed to have the outer periphery of second region A2 partially coinciding with only two sides among the four sides of semiconductor layer 40 rectangular in shape.

In the examples of the embodiment shown in FIG. 2A and FIG. 2B, in the plan view, second gate pad 129 is disposed closest to a corner portion defined by, among outer peripheral sides of second region A2, two outer peripheral sides that are not adjacent to first region A1. In second region A2, second gate pad 129 is disposed farthest from boundary line 90 with first region A1. It should be noted that, in the embodiment, that a pad is closest to a corner portion means that no other pad is disposed between the pad and the corner portion.

Moreover, in the plan view, first gate pad 119 is disposed in a position opposite to second gate pad 129 with drain pad 151 interposed therebetween.

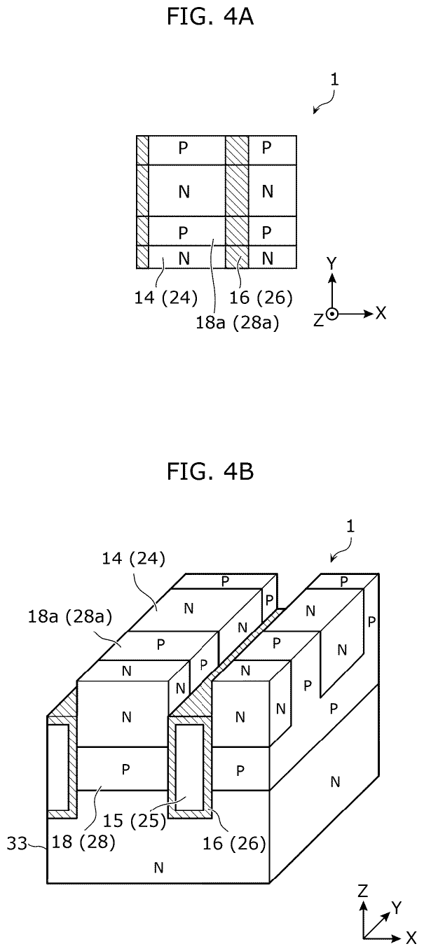

FIG. 4A and FIG. 4B are a planar schematic diagram and a perspective schematic diagram showing an approximate single unit configuration of transistor 10 or transistor 20 that is repeatedly formed in an X direction and a Y direction of semiconductor device 1 according to the embodiment, respectively. For the sake of clarity, FIG. 4A and FIG. 4B do not show semiconductor substrate 32, metal layer 41, passivation layer 35, first source electrode 11 or second source electrode 21, and interlayer insulating layer 34.

It should be noted that the Y direction is a direction that is parallel to the surface of semiconductor layer 40 and in which first gate trench 17 extends. The X direction is a direction that is parallel to the surface of semiconductor layer 40 and orthogonal to the Y direction. A Z direction is a direction that is orthogonal to both the X direction and the Y direction and indicates a height direction of semiconductor device 1.

As shown in FIG. 4A and FIG. 4B, transistor 10 includes first connector 18a that electrically connects first body region 18 and first source electrode 11. First connector 18a is a region of first body region 18 in which first source region 14 is not provided, and is of the second conductivity type that is the same as first body region 18. First source region 14 and first connector 18a are alternately and periodically disposed in the Y direction. The same applies to transistor 20.

In semiconductor device 1 according to the present disclosure, assuming that the first conductivity type is N-type and the second conductivity type is P-type, first source region 14, second source region 24, drain lead-out region 38, semiconductor substrate 32, and low-concentration impurity layer 33 are N-type semiconductors, and first body region 18, first connector 18a, second body region 28, and second connector 28a are P-type semiconductors.

### [2. Operation of Semiconductor Device]

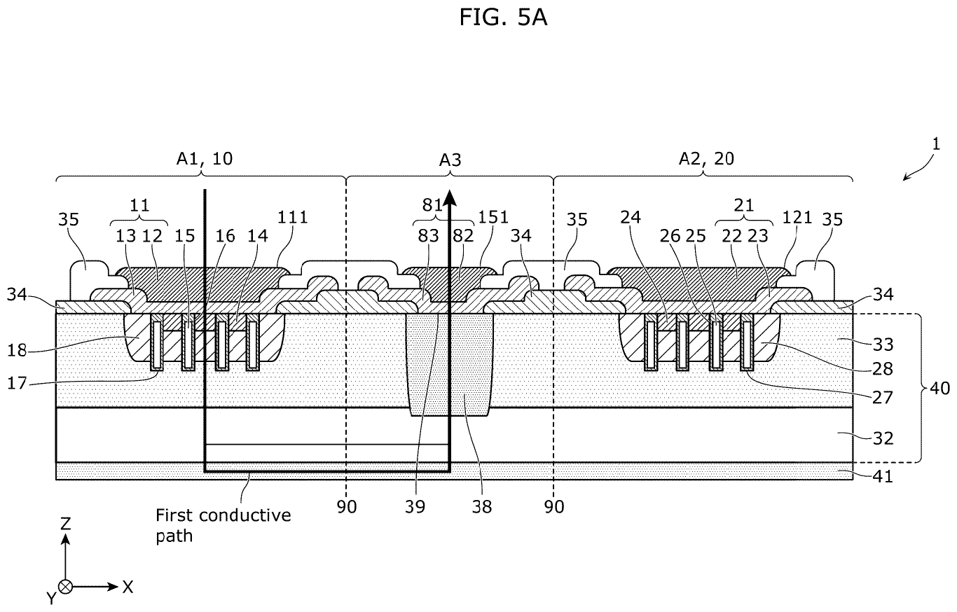

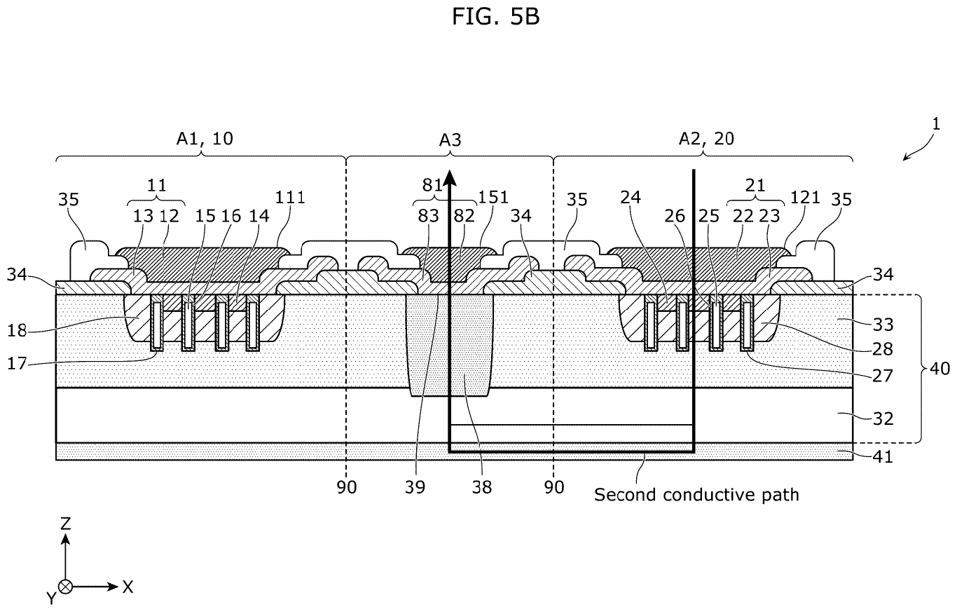

Hereinafter, a first conductive path and a second conducive path of semiconductor device 1 and how to drive semiconductor device 1 are described with reference to FIG. 5A and FIG. 5B. FIG. 5A and FIG. 5B each are a cross-sectional schematic diagram showing a conductive path of semiconductor device 1 according to the embodiment.

In semiconductor device 1 according to the embodiment, it is assumed that a current enters through one of first source pad 111 of first region A1 or second source pad 121 of second region A2 as an inlet, flows through the common drain region and backside drain electrode 41, and exits through drain pad 151 of third region A3 as an outlet. In other words, driving constitutes a conductive path from first source pad 111 to second source pad 121 or an other conductive path that is the reverse of the conductive path is not assumed in the embodiment.

In semiconductor device 1, a conductive path in which a current enters through first source pad 111 of first region A1 as an inlet and exits through drain pad 151 of third region A3 as an outlet is referred to as the first conductive path. A conductive path in which a current enters through second source pad 121 of second region A2 as an inlet and exits through drain pad 151 of third region A3 as an outlet is referred to as the second conductive path.

In the first conductive path shown in FIG. 5A, a current flows as stated below. In semiconductor device 1, by applying a high voltage and a low voltage to first source electrode 11 and frontside drain electrode 81, respectively, and applying (ON control) a voltage greater than or equal to a threshold value to first gate electrode 19 (first gate conductor 15) with respect to first source electrode 11, a conducting channel is formed in the vicinity of first gate insulating film 16 in first body region 18. When the conducting channel is formed, the current flows in a path from first source electrode 11-first source region 14-the conducting channel formed in first body region 18-low-concentration impurity layer 33-semiconductor substrate 32-metal layer 41-semiconductor substrate 32-drain lead-out region 38-frontside drain electrode 81, and semiconductor device 1 becomes conductive.

When an electric potential of first source electrode 11 is sufficiently high relative to an electric potential of frontside drain electrode 81, the voltage greater than or equal to the threshold value need not be applied (ON control) to first gate electrode 19 (first gate conductor 15). In this case, although the conducting channel is not formed in the vicinity of first gate insulating film 16 in first body region 18, a current flows in a path from first source electrode 11-first connector 18a-first body region 18-low-concentration impurity layer 33-semiconductor substrate 32-metal layer 41-semiconductor substrate 32-drain lead-out region 38-frontside drain electrode 81, and semiconductor device 1 becomes conductive.

Both of the above cases apply to the first conductive path. In the latter case, since a PN junction is in a contact surface between first body region 18 and low-concentration impurity layer 33, a conductive resistance becomes relatively high. In the former case, since the current flows via the conducting channel, a conductive resistance becomes relatively low.

In either case, it should be noted that when the first conductive path is conducted, a PN junction in a contact surface between second body region 28 and low-concentration impurity layer 33 in transistor 20 is caused to serve as a body diode. This prevents conduction from first source pad 111 to second source pad 121. When only the first conductive path is used in semiconductor device 1, the voltage greater than or equal to the threshold value need not be applied (OFF control) to second gate electrode 29 (second gate conductor 25) of transistor 20.

In the second conductive path shown in FIG. 5B, a current flows as stated below. In semiconductor device 1, by applying a high voltage and a low voltage to second source electrode 21 and frontside drain electrode 81, respectively, and applying (ON control) a voltage greater than or equal to a threshold value to second gate electrode 29 (second gate conductor 25) with respect to second source electrode 21, a conducting channel is formed in the vicinity of second gate insulating film 26 in second body region 28. When the conducting channel is formed, the current flows in a path from second source electrode 21-second source region 24-the conducting channel formed in second body region 28-low-concentration impurity layer 33-semiconductor substrate 32-metal layer 41-semiconductor substrate 32-drain lead-out region 38-frontside drain electrode 81, and semiconductor device 1 becomes conductive.

When an electric potential of second source electrode 21 is sufficiently high relative to an electric potential of frontside drain electrode 81, the voltage greater than or equal to the threshold value need not be applied (ON control) to second gate electrode 29 (second gate conductor 25). In this case, although the conducting channel is not formed in the vicinity of second gate insulating film 26 in second body region 28, a current flows in a path from second source electrode 21-second connector 28a-second body region 28-low-concentration impurity layer 33-semiconductor substrate 32-metal layer 41-semiconductor substrate 32-drain lead-out region 38-frontside drain electrode 81, and semiconductor device 1 becomes conductive.

Both of the above cases apply to the second conductive path. In the latter case, since a PN junction is in a contact surface between second body region 28 and low-concentration impurity layer 33, a conductive resistance becomes relatively high. In the former case, since the current flows via the conducting channel, a conductive resistance becomes relatively low.

In either case, it should be noted that when the second conductive path is conducted, a PN junction in a contact surface between first body region 18 and low-concentration impurity layer 33 in transistor 10 is caused to serve as a body diode. This prevents conduction from second source pad 121 to first source pad 111. When only the second conductive path is used in semiconductor device 1, the voltage greater than or equal to the threshold value need not be applied (OFF control) to first gate electrode 19 (first gate conductor 15) of transistor 10.

It should be noted that, as shown in FIG. 5A and FIG. 5B, although most of a current that flows inside semiconductor device 1 in a horizonal direction passes through metal layer 41 having a low resistivity both in the first conductive path and the second conductive path, a portion of the current may flow through semiconductor substrate 32.

### [3. Example of Using Semiconductor Device]

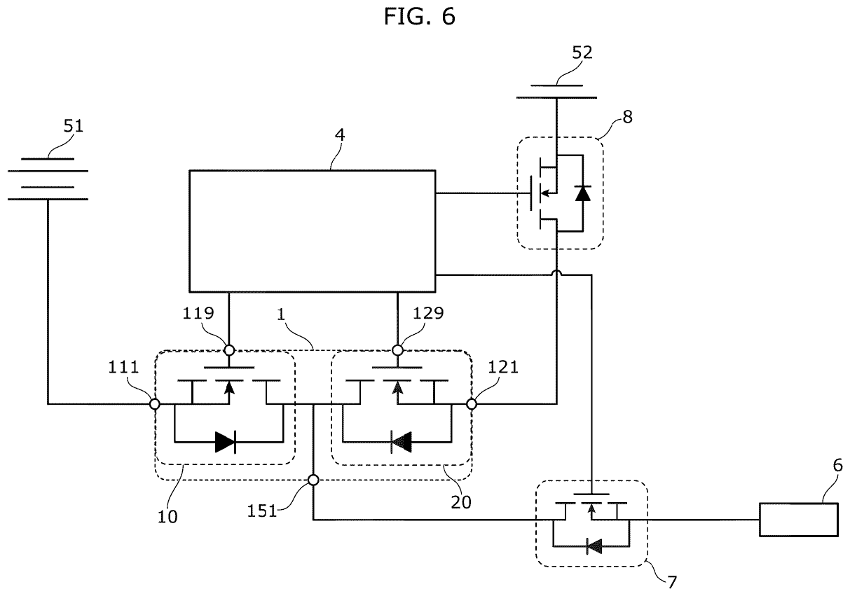

FIG. 6 is a circuit diagram showing a portion of a power supply system that passes a current from each of first power source 51 and second power source 52 that are removable to load 6 via semiconductor device 1 according to the embodiment. Here, an electric potential of first power source 51 is higher than an electric potential of second power source 52 with reference to an electric potential of load 6.

Semiconductor device 1 according to the embodiment is disposed to server a function of integrating two paths of power supply from first power source 51 having the higher electric potential and power supply from second power source 52 having the lower electric potential into one path toward load 6 having a low electric potential.

The maximum value of a current that flows due to the power supply from first power source 51 having the higher electric potential is denoted as I1 [A], and the maximum value of a current that flows due to the power supply from second power source 52 having the electric potential lower than the electric potential of first power source 51 is denoted as I2 [A]. It can be safely considered that I1 and 12 are each considered as a maximum current value in specification in a corresponding one of the first conductive path and the second conductive path described in a product data sheet of semiconductor device 1 according to the embodiment.

Since first power source 51 and second power source 52 have an electric potential relation, I1>I2 holds. A first power source 51 side through which relatively large current I1 flows is connected to first source pad 111 of transistor 10 having a large area in the plan view in semiconductor device 1. A second power source 52 side through which relatively small current I2 flows is connected to second source pad 121 of transistor 20 having a small area in the plan view in semiconductor device 1.

It should be noted that switching element 7 (e.g., a single vertical MOS transistor) is located between semiconductor device 1 and load 6. Moreover, switching element 8 (e.g., a single vertical MOS transistor) is located between semiconductor device 1 and second power source 52. Switching element 7, switching element 8, and semiconductor device 1 are connected to control IC 4. Control IC 4 controls ON and OFF of switching element 7, switching element 8, transistor 10, and transistor 20 separately.

First, a state in which only first power source 51 is connected and second power source 52 is not connected (a state in which second power source 52 is not present in FIG. 6) is described. At this time, control IC 4 performs ON control on switching element 7 and OFF control on transistor 20, and first power source 51 supplies power to load 6 via the first conductive path in semiconductor device 1. In addition, when control IC 4 performs ON control on transistor 10, it is possible to reduce a conductive resistance in the first conductive path.

The first conductive path is a conductive path inside semiconductor device 1 and, as described above, a conductive path in which a current enters through first source pad 111 of transistor 10 as an inlet and exits through drain pad 151 as an outlet. When only the first conductive path is conducted, the OFF control is performed on transistor 20. Since the OFF control is performed on transistor 20, it is possible to cause a current that flows due to the power supply from first power source 51 not to flow toward the second power source 52 side.

Next, a state in which only second power source 52 is connected and first power source 51 is not connected (a state in which first power source 51 is not present in FIG. 6) is described. At this time, control IC 4 performs ON control on switching element 7 and OFF control on transistor 10, and second power source 52 supplies power to load 6 via the second conductive path in semiconductor device 1. In addition, when control IC 4 performs ON control on transistor 20, it is possible to reduce a conductive resistance in the second conductive path.

The second conductive path is a conductive path inside semiconductor device 1 and, as described above, a conductive path in which a current enters through second source pad 121 of transistor 20 as an inlet and exits through drain pad 151 as an outlet. When only the second conductive path is conducted, the OFF control is performed on transistor 10. Since the OFF control is performed on transistor 10, it is possible to cause a current that flows due to the power supply from second power source 52 not to flow toward the first power source 51 side.

When first power source 51 and second power source 52 are both connected (the state in FIG. 6), control IC 4 first performs OFF control on switching element 8 and creates a state in which only first power source 51 supplies power. This is because first power source 51 has the higher electric potential and is superior in power supply. Additionally, by control IC 4 performing ON control on switching element 7 and OFF control on transistor 20, first power source 51 supplies power to load 6 via the first conductive path. When control IC 4 performs ON control on transistor 10, it is possible to reduce a conductive resistance in the first conductive path.

### [4. Advantageous Effects of Semiconductor Device]

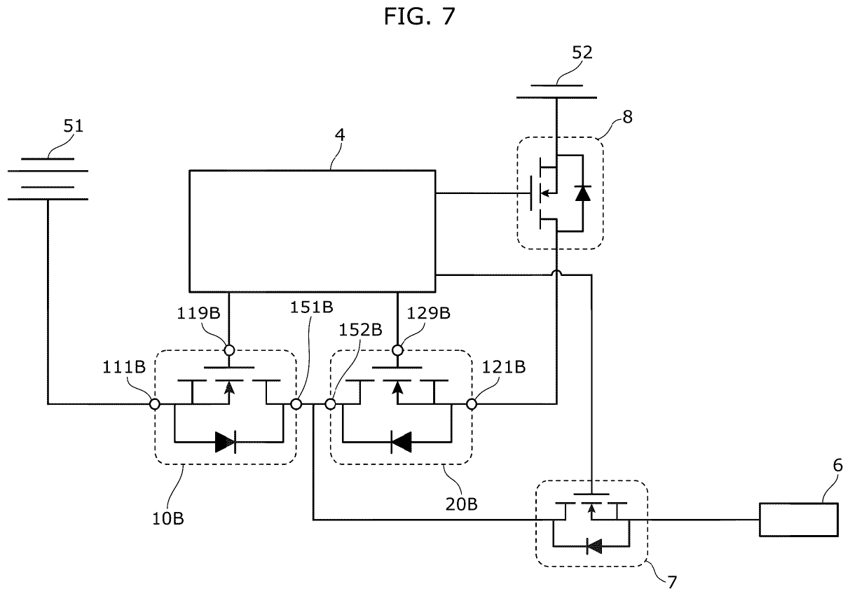

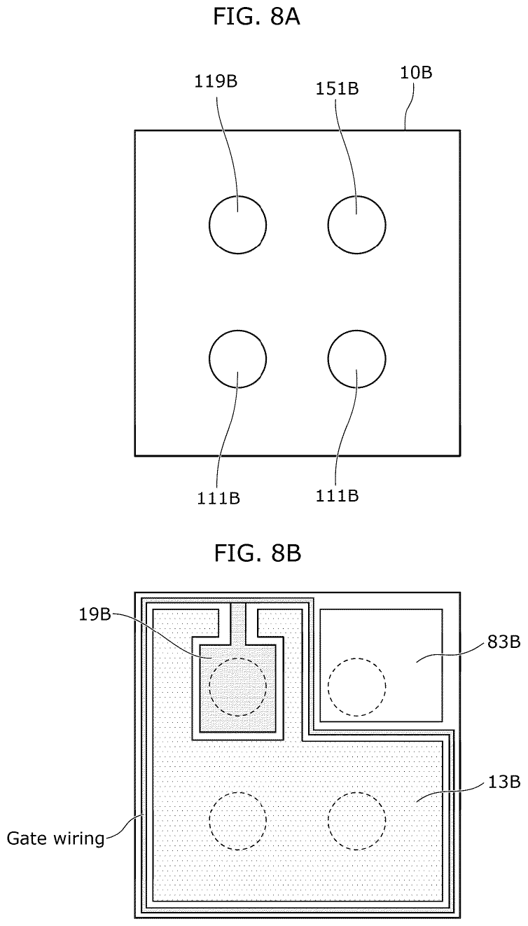

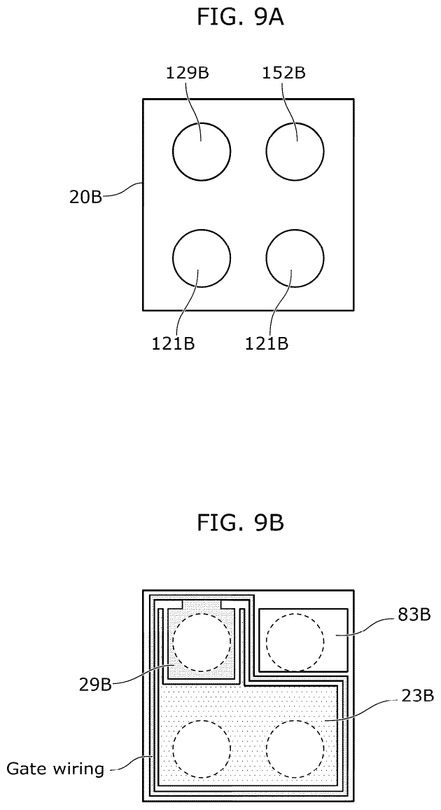

FIG. 7 shows a comparative example when semiconductor device 1 according to the embodiment is not used in the power supply system shown in FIG. 6. In the comparative example, instead of semiconductor device 1 according to the embodiment, for example, vertical MOS transistor 10B (hereinafter referred to as transistor 10B) that includes a single configuration and of which examples of the structure are shown by planar schematic diagrams in FIG. 8A and FIG. 8B and vertical MOS transistor 20B (hereinafter referred to as transistor 20B) that includes a single configuration and of which examples of the structure are shown by planar schematic diagrams in FIG. 9A and FIG. 9B are used.

Constituent elements of transistor 10B and transistor 20B similar to those of semiconductor device 1 according to the embodiment are assigned the reference signs of the latter to which B is added. However, for the sake of distinction, different reference signs are assigned to drain pads between transistor 10B (including drain pad 151B) and transistor 20B (including drain pad 152B).

As with the planar schematic diagram (FIG. 2B) showing semiconductor device 1 according to the embodiment, FIG. 8B and FIG. 9B each show a state immediately after portion 13B (23B) of a source electrode, gate electrode 19B (29B), gate wiring, and portion 83B of a frontside drain electrode are provided on the front face side of semiconductor layer 40. For the sake of clarity, pads that cannot be seen at this moment are indicated by dashed lines in FIG. 8B and FIG. 9B.

The area of portion 13B of a source electrode of transistor 10B in the plan view is equal to the area of portion 13 of first source electrode 11 of transistor 10 included in semiconductor device 1 according to the embodiment in the plan view. Accordingly, it can be safely considered that a conductive resistance of a path in which a current flows from first power source 51 to load 6 via transistor 10B in FIG. 7 is equal to the conductive resistance of the first conductive path of semiconductor device 1 according to the embodiment in FIG. 6.

Moreover, the area of portion 23B of a source electrode of transistor 20B in the plan view is equal to the area of portion 23 of second source electrode 21 of transistor 20 included in semiconductor device 1 according to the embodiment in the plan view. Accordingly, it can be safely considered that a conductive resistance of a path in which a current flows from second power source 52 to load 6 via transistor 20B in FIG. 7 is equal to the conductive resistance of the second conductive path of semiconductor device 1 according to the embodiment in FIG. 6.

In the power supply system shown in FIG. 7, when only first power source 51 is connected (second power source 52 is not present in FIG. 7), OFF control is performed on transistor 20B, and a current that flows due to the power supply from first power source 51 is caused not to flow toward the second power source 52 side. ON control is performed on transistor 10B by applying a voltage greater than or equal to a threshold value to gate pad 119B, and the current that flows due to the power supply from first power source 51 enters through source pad 111B of transistor 10B and exits through drain pad 151B. As shown in FIG. 8A and FIG. 8B, the reason why the area of transistor 10B (the area of portion 13B of the source electrode) in the plan view is relatively large is because the current that flows due to the power supply from first power source 51 is relatively large.

In the power supply system shown in FIG. 7, when only second power source 52 is connected (first power source 51 is not present in FIG. 7), OFF control is performed on transistor 10B, and a current that flows due to the power supply from second power source 52 is caused not to flow toward the first power source 51 side. ON control is performed on transistor 20B by applying a voltage greater than or equal to a threshold value to gate pad 129B, and the current that flows due to the power supply from second power source 52 enters through source pad 121B of transistor 20B and exits through drain pad 152B. As shown in FIG. 9A and FIG. 9B, the reason why the area of transistor 20B (the area of portion 23B of the source electrode) in the plan view is relatively small is because the current that flows due to the power supply from second power source 52 is relatively small.

As stated above, transistor 10B in the power supply system according to the comparative example shown in FIG. 7 serves the same function as transistor 10 in the power supply system shown in FIG. 6, which is included in semiconductor device 1 according to the embodiment. Likewise, transistor 20B in the power supply system according to the comparative example shown in FIG. 7 serves the same function as transistor 20 in the power supply system shown in FIG. 6, which is included in semiconductor device 1 according to the embodiment.

However, in a circuit substrate including the power supply system according to the comparative example shown in FIG. 7, it is necessary to ensure the area of each of transistor 10B and transistor 20B and a certain margin for installation to be provided between transistor 10B and transistor 20B. Additionally, since each of transistor 10B and transistor 20B includes a drain pad (151B, 152B) in the plan view, transistor 10B and transistor 20B each include a structure that requires a certain area.

On the other hand, in a circuit substrate including the power supply system shown in FIG. 6, it is possible to integrate transistor 10B and transistor 20B according to the comparative example into one semiconductor device by using semiconductor device 1 according to the embodiment. Accordingly, it is possible to eliminate the need for the certain margin for installation to be provided between transistor 10B and transistor 20B that is required in the circuit substrate including the power supply system according to the comparative example, and further it is possible to make common the respective drain pads (151B, 152B) included in transistor 10B and transistor 20B as one drain pad. For these reasons, it is possible to reduce the area necessary for the circuit substrate. The circuit substrate including the power supply system shown in FIG. 6 makes it possible not only to reduce the substrate itself but also to provide other components in a resultant surplus portion, compared to the comparative example.

Accordingly, semiconductor device 1 according to the embodiment is facedown mountable, chip-size-package type semiconductor device 1, and includes: semiconductor layer 40 that includes semiconductor substrate 32 on a back face side and is divided into first region A1, second region A2, and third region A3 that do not overlap each other and are not dispersedly disposed in a plan view of semiconductor device 1; first vertical metal-oxide-semiconductor (MOS) transistor 10 an entirety of which is provided in first region A1 of semiconductor layer 40; second vertical MOS transistor 20 an entirety of which is provided in second region A2 of semiconductor layer 40; and metal layer 41 that is provided in contact with the back face side of semiconductor layer 40. Semiconductor substrate 32 is a common drain region of first vertical MOS transistor 10 and second vertical MOS transistor 20. In the plan view, first source pad 111 and first gate pad 119 of first vertical MOS transistor 10 are provided at positions within first region A1. In the plan view, second source pad 121 and second gate pad 129 of second vertical MOS transistor 20 are provided at positions within second region A2. In the plan view, drain pad 151 that is connected to the common drain region is provided at a position within third region A3. In the plan view, first region A1 and second region A2 are disposed with third region A3 interposed therebetween. In the plan view, third region A3 is adjacent to first region A1 and second region A2. In the plan view, an area of first region A1 is larger than an area of second region A2.

In semiconductor device 1 according to the embodiment, the first conductive path uses first source pad 111 in first region A1 as an inlet and drain pad 151 in third region A3 as an outlet. For this reason, when first region A1 and third region A3 are adjacent to each other in the plan view, it is advantageous because it is possible to reduce a conductive resistance by shortening the first conductive path. Similarly, the second conductive path uses second source pad 121 in second region A2 as an inlet and drain pad 151 in third region A3 as an outlet. For this reason, when second region A2 and third region A3 are adjacent to each other in the plan view, it is advantageous because it is possible to reduce a conductive resistance by shortening the second conductive path.

Accordingly, in the plan view, first region A1 and second region A2 may be disposed with third region A3 interposed therebetween, and third region A3 may be adjacent to first region A1 and second region A2.

In semiconductor device 1 according to the embodiment, the emphasis is placed on reducing a conductive resistance of the first conductive path. For this reason, as shown in FIG. 2A or FIG. 2B, in the plan view, the boundary length between first region A1 and third region A3 may be greater than the boundary length between second region A2 and third region A3. When an arrangement in the plan view of semiconductor device 1 is made as above, it is possible to expand a portion of the first conductive path that has the highest current density (extend a boundary length). Accordingly, it is possible to reduce the conductive resistance.

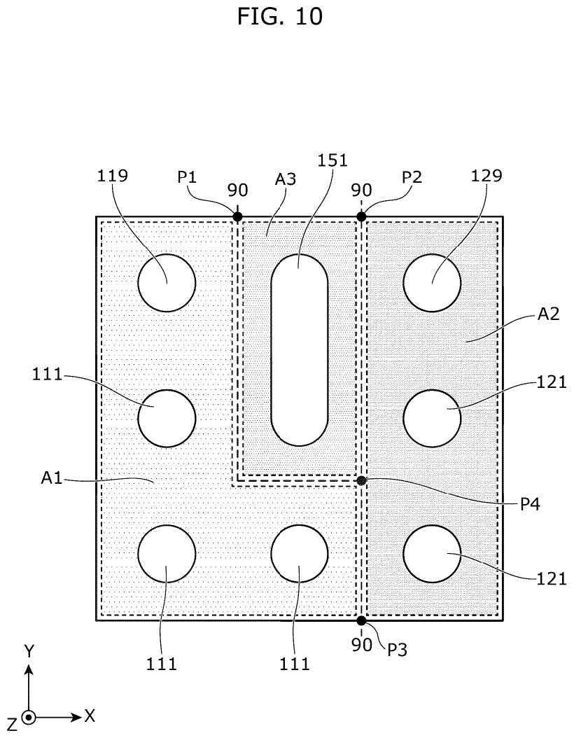

Variation 2 as shown in, for example, FIG. 10 also makes it possible to achieve the advantageous effect as described above. FIG. 10 is a planar schematic diagram obtained by changing an occupancy ratio between first region A1 and second region A2 in semiconductor device 1 according to the embodiment.

Moreover, as shown in FIG. 2A and FIG. 2B, semiconductor layer 40 may be rectangular in shape in the plan view, and first region A1 may be disposed to have the outer periphery of first region A1 partially coinciding with the four sides of semiconductor layer 40. When an arrangement in the plan view of semiconductor device 1 is made as above, it is possible not only to increase the area of first region A1 but also to provide the first conductive path as broadly as possible. Accordingly, it is possible to reduce local occurrence of a portion that is heated to a high temperature by current crowding.

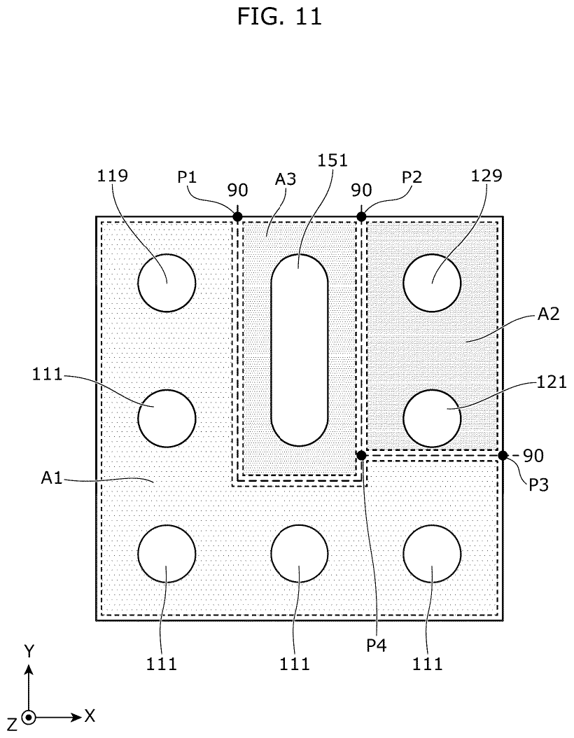

Variation 3 as shown in, for example, FIG. 11 also makes it possible to achieve the advantageous effect as described above. FIG. 11 is a planar schematic diagram obtained by changing an occupancy ratio between first region A1 and second region A2 in semiconductor device 1 according to the embodiment.

As shown in FIG. 2B, a portion in which second gate electrode 29 is disposed cannot contribute to conduction. For this reason, in the plan view, second gate electrode 29 may be disposed farthest from a portion that may become a barrier to the second conductive path, in second region A2. In other words, second gate electrode 29 may be disposed as far from boundary line 90 between second region A2 and third region A3 as possible at which a current density is highest in the second conductive path.

Accordingly, in the plan view, second gate electrode 29, that is, second gate pad 129 may be disposed closest to a corner portion defined by, among the outer peripheral sides of second region A2, two outer peripheral sides that are not adjacent to third region A3. In the example shown in FIG. 2B, second gate pad 129 is disposed closest to an upper right corner portion in the plan view.

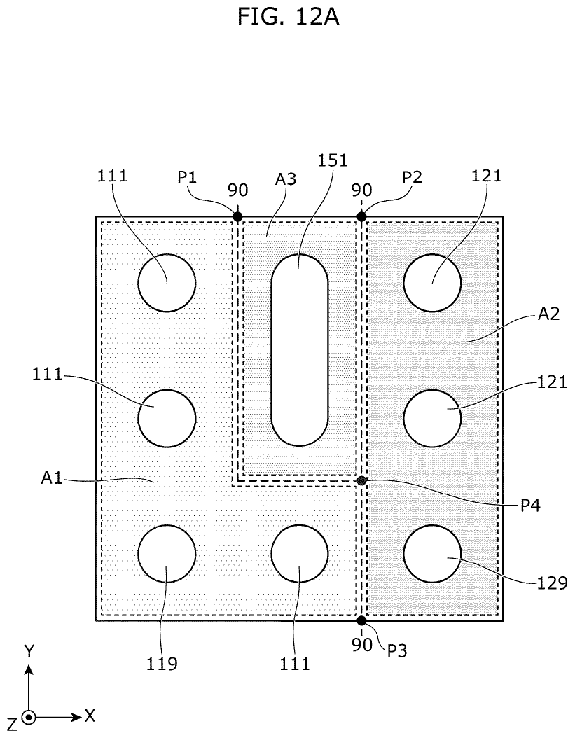

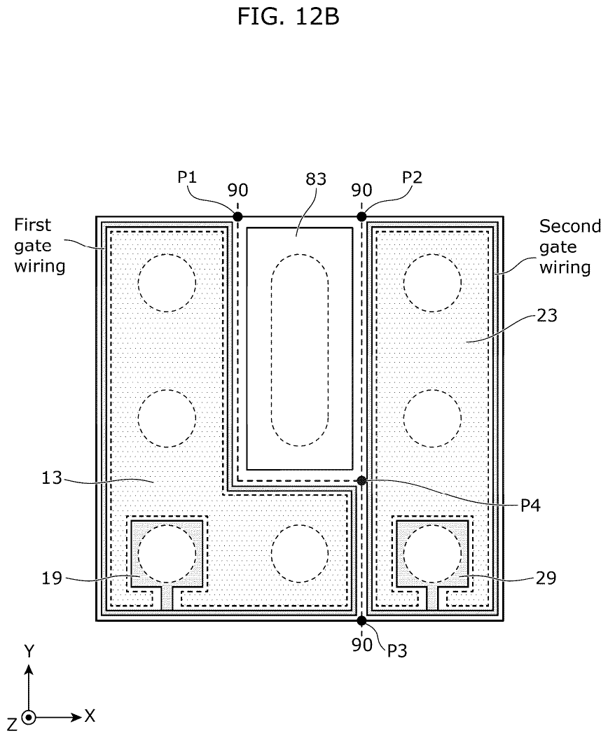

Variation 4 as shown in, for example, FIG. 12A and FIG. 12B also makes it possible to achieve the advantageous effect as described above. FIG. 12A and FIG. 12B each are a planar schematic diagram obtained by changing the positions of first gate electrode 19, first gate pad 119, second gate electrode 29, and second gate pad 129 in Variation 2 of semiconductor device 1 according to the embodiment. It should be noted that FIG. 12B shows a state immediately after portion 13 of the first source electrode, portion 23 of the second source electrode, first gate electrode 19, second gate electrode 29, the first gate wiring, the second gate wiring, and portion 83 of the frontside drain electrode are provided on the front side of semiconductor layer 40. For the sake of clarity, pads that cannot be seen at this moment are indicated by dashed lines in FIG. 12B.

A comparison of Variation 4 shown in FIG. 12B with the example shown in FIG. 2B shows that, in Variation 4, in second region A2, second gate pad 129 is disposed closest to boundary line 90 between first region A1 and second region A2 (the dashed line from P3 to P4) in the plan view. For this reason, it is possible to widely use a region along boundary line 90 between second region A2 and third region A3 (the dashed line from P2 to P4) at which the current density is highest in the second conductive path.

Moreover, it can be also said that, in Variation 4, in the plan view, second gate pad 129 is disposed closest to the corner portion farthest from drain pad 151 among corner portions defined by the outer peripheral sides of second region A2. For this reason, it is possible to widely use the region along boundary line 90 between second region A2 and third region A3 (the dashed line from P2 to P4). Similarly, in the plan view, first gate pad 119 is disposed closest to the corner portion farthest from drain pad 151 among corner portions defined by the outer peripheral sides of first region A1. For this reason, it is possible to widely use a region along boundary line 90 between first region A1 and third region A3 (the dashed line from P1 to P4).

The following refers back to the example shown in FIG. 6 in which semiconductor device 1 according to the embodiment is used. In a transistor in the ON state, since a total gate width generally increases when the area of the transistor in a plan view is large, a conductive resistance decreases. In other words, the area of the transistor in the plan view and the conductive resistance are in an inverse proportion relation on the whole.

In semiconductor device 1, area a1 of transistor 10 constituting the first conductive path in the plan view is larger than area a2 of transistor 20 constituting the second conductive path in the plan view. For this reason, the first conductive path has a lower conductive resistance and is a path suitable for passing a relatively large current.

Conductive resistance R1 [Ω] of the first conductive path may be determined in consideration of maximum value I1 [A] of a current that flows due to power supply from first power source 51. Similarly, conductive resistance R2 [Ω] of the second conductive path may be determined in consideration of maximum value I2 [A] of a current that flows due to power supply from second power source 52. Accordingly, in semiconductor device 1 according to the embodiment, the respective areas of transistor 10 and transistor 20 may be determined to achieve a conductive resistance suitable for each of the first conductive path and the second conducive path.

However, when area a2 of transistor 20 in the plan view determined as described above is excessively small, electrostatic discharge (ESD) tolerance may deteriorate, and semiconductor device 1 as a whole may not successfully maintain an ESD rated value. When area a2 of transistor 20 in the plan view is increased to maintain the ESD rated value, the conductive resistance of the second conductive path is excessively reduced, and it is difficult to limit the current from second power source 52 to a desired magnitude.

In view of this, the inventors discovered that by appropriately designing the size (area) and the position of drain contact region 39 in third region A3 in the plan view aside from area a2 of transistor 20 in the plan view, semiconductor device 1 controls a conductive resistance in the second conductive path.

The following description is based on the premise that area a2 of transistor 20 in the plan view is increased as much as necessary to maintain an ESD rated value in semiconductor device 1 according to the embodiment. In other words, it is considered that a conductive resistance of the second conductive path is excessively reduced in semiconductor device 1 according to the embodiment.

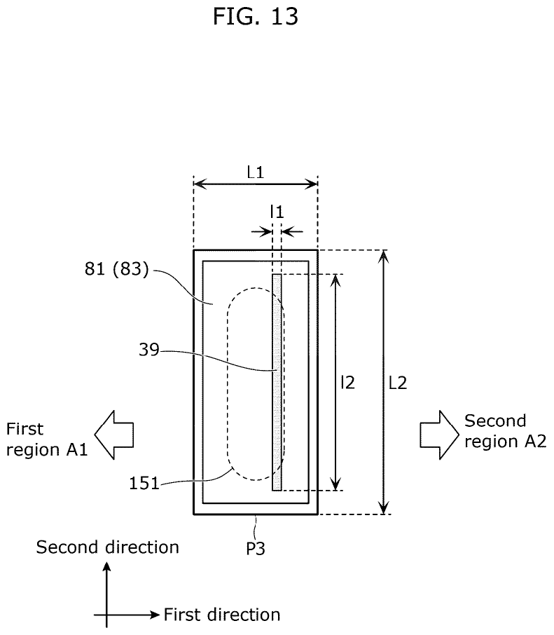

FIG. 13 is a planar schematic diagram obtained by cutting out only third region A3 from the planar schematic diagram of semiconductor device 1 shown in FIG. 2B.

As shown in FIG. 1 and FIG. 3, drain contact region 39 is a region in which drain lead-out region 38 and portion 83 of frontside drain electrode 81 are connected. Accordingly, drain contact region 39 is a portion contained in third region A3 in the plan view.

In an example shown in FIG. 13, both third region A3 and drain contact region 39 are rectangular in shape in the plan view. A direction (the X direction in FIG. 13) along the shorter sides of third region A3 rectangular in shape in the plan view is defined as a first direction, and a direction (the Y direction in FIG. 13) along the longer sides of third region A3 is defined as a second direction. The first direction and the second direction are orthogonal to each other.

In the plan view, the length of a side of third region A3 in the first direction is denoted by L1 [μm], and the length of a side of third region A3 in the second direction is denoted by L2 [μm]. Additionally, in the plan view, the length of a side of drain contact region 39 in the first direction is denoted by I1 [μm], and the length of a side of drain contact region 39 in the second direction is denoted by I2 [μm].

The inventors set conditions of I1≤L1/4 and I2≈L2 with regard to the area of drain contact region 39 in the plan view, with a view to avoid an excessive reduction of the conductive resistance in the second conductive path.

With regard to I2≈L2, to be precise, as shown in FIG. 13, I2 is less than L2 by end margins for installation in the second direction. The condition I1≤L1/4 is for reducing the area of drain contact region 39 to at least ¼ or less of the area of third region A3 and adjusting the position of drain contact region 39 in the plan view accordingly using a distance from second region A2.

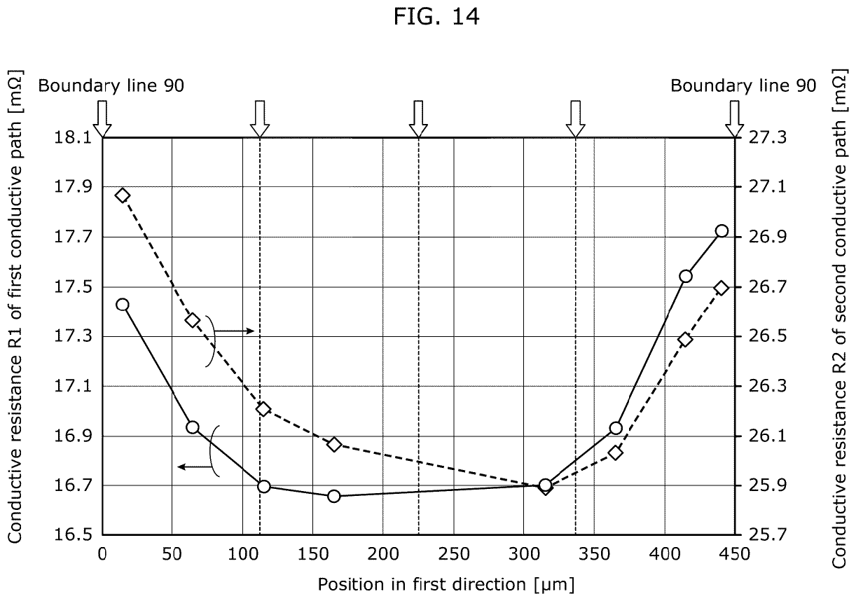

Based on such an idea, the inventors examined a case in which semiconductor device 1 in which the size and shape of drain contact region 39 in the plan view are set as shown in FIG. 13 is used in the circuit shown by the circuit diagram of FIG. 6. FIG. 14 is a graph obtained by plotting results of calculating conductive resistance R1 of the first conductive path when ON control is performed on transistor 10 and OFF control is performed on transistor 20 and conductive resistance R2 of the second conductive path when ON control is performed on transistor 20 and OFF control is performed on transistor 10. Conductive resistance R1 of the first conductive path is indicated by circular markers and represented by the left vertical axis. Conductive resistance R2 of the second conductive path is indicated by rhombic markers and represented by the right vertical axis.

The horizontal axis of FIG. 14 represents a position in the first direction, in third region A3 in the plan view. In FIG. 13, a reference position is the left end of third region A3, that is, on boundary line 90 between first region A1 and third region A3. In addition, the horizontal axis represents a position of the center of drain contact region 39.

Arrows shown in the upper portion of FIG. 14 indicate, from left to right in the first direction, the reference position, a position away from the reference position by L1/4, a position away from the reference position by L1/2, a position away from the reference position by 3×L1/4, and a position away from the reference position by L1, that is, a position on boundary line 90 between third region A3 and second region A2. Third region A3 is divided into four sections having the equal area in the plan view, at the above positions. The four sections are referred to as a fourth region, a fifth region, a sixth region, and a seventh region from left to right in the first direction.

It should be noted that, in the calculation results shown by the graph of FIG. 14, semiconductor device 1 is square in shape whose side has a length of 1.5 [mm] in the plan view, and the division of first region A1, second region A2, and third region A3 and the shape and arrangement of each pad and electrode are identical to those shown in FIG. 2A and FIG. 2B. The size of third region A3 in the plan view is L1=450 [μm] and L2=1000 [μm]. Additionally, the size of drain contact region 39 is I1=3 [μm] and I2=980 [μm].

The reason why data are plotted with a certain distance kept from each of the left end and the right end for the horizontal axis in FIG. 14 is because the margins for installation are added to portion 83 of frontside drain electrode 81 inside third region A3 in the plan view.

It is clear from FIG. 14 that when drain contact region 39 is disposed close to the center of third region A3 in the plan view, both R1 and R2 become minimum. Here, the location close to the center refers to the fifth region or the sixth region. That drain contact region 39 is in, for example, the fourth region means that the center of drain contact region 39 is in the fourth region in the plan view. This does not necessarily mean that the entirety of drain contact region 39 is contained by the fourth region.

Moreover, it is clear from FIG. 14 that R2 tends to increase as drain contact region 39 becomes distant from second region A2 in the plan view (the position of drain contact region 39 is shifted toward the fourth region). Such a tendency seen in FIG. 14 becomes more remarkable as the area of drain contact region 39 is smaller, and becomes difficult to see when the area of drain contact region 39 is increased beyond ¼ of the area of third region A3.

Accordingly, in semiconductor device 1 according to the embodiment, semiconductor substrate 32 may be of a first conductivity type and include an impurity having a first concentration, semiconductor layer 40 may include low-concentration impurity layer 33 of the first conductivity type, low-concentration impurity layer 33 being provided on semiconductor substrate 32 and including an impurity having a second concentration lower than the first concentration, in the plan view, drain lead-out region 38 of the first conductivity type may be provided in third region A3, drain lead-out region 38 being connected to the common drain region (semiconductor substrate 32) and including an impurity having a concentration higher than the first concentration, in the plan view, portion 83 of frontside drain electrode 81 may be provided at a position within third region A3, frontside drain electrode 81 being in contact with a surface of semiconductor layer 40 and connected to drain lead-out region 38, and in the plan view, an area of drain contact region 39 in which portion 83 of frontside drain electrode 81 and drain lead-out region 38 are connected may be at most ¼ of an area of third region A3.

Moreover, when drain contact region 39 is substantially rectangular in shape having the longitudinal direction in the second direction in the plan view, it is possible to achieve almost the same advantageous effects.

Accordingly, in the plan view, third region A3 may be rectangular in shape, maximum width I1 of drain contact region 39 in a first direction that is parallel to shorter side L1 of third region A3 may be less than maximum width I2 of drain contact region 39 in a second direction that is orthogonal to the first direction and parallel to longer side L2 of third region A3 in the plan view, and in the plan view, maximum width I1 of drain contact region 39 in the first direction may be at most ¼ of a length of shorter side L1 of third region A3.

According to FIG. 14, when drain contact region 39 is in the fifth region, conductive resistance R1 of the first conductive path almost constantly remains minimum. In contrast, conductive resistance R2 of the second conductive path increases as drain contact region 39 is disposed closer toward the fourth region. For this reason, when drain contact region 39 is disposed in the fifth region, it is possible to increase only R2 while reducing R1.

Accordingly, in the plan view, third region A3 may be divided into a fourth region, a fifth region, a sixth region, and a seventh region that are equal in area in the first direction, in the plan view, the fourth region, the fifth region, the sixth region, and the seventh region may be arranged in the first direction in stated order from boundary line 90 between first region A1 and third region A3 to boundary line 90 between second region A2 and third region A3, and in the plan view, a center of drain contact region 39 may be located in the fifth region.

Drain contact region 39 may be disposed close to the boundary with the fourth region, in the fifth region. For example, drain contact region 39 may be disposed across the boundary between the fourth region and the fifth region. When drain contact region 39 is disposed in this manner, it is possible to avoid an excessive reduction of R2.

Both R1 and R2 increase when drain contact region 39 is in the fourth region and as drain contact region 39 is disposed closer to boundary line 90 between first region A1 and third region A3 (the reference position in the first direction). However, R2 has a higher rate of increase. This is because drain contact region 39 is away from boundary line 90 between second region A2 and third region A3.

Accordingly, in the plan view, third region A3 may be divided into a fourth region, a fifth region, a sixth region, and a seventh region each of which is equal in area in the first direction, in the plan view, the fourth region, the fifth region, the sixth region, and the seventh region may be arranged in the first direction in stated order from boundary line 90 between first region A1 and third region A3 to boundary line 90 between second region A2 and third region A3, and in the plan view, a center of drain contact region 39 may be located in the fourth region.

It is possible to increase a difference between R1 and R2 as drain contact region 39 is disposed closer to boundary line 90 between first region A1 and third region A3. When drain contact region 39 is disposed in this manner, it is possible to avoid an excessive reduction of R2 in response to an increase in the area of second region A2 in the plan view.

It should be noted that in the case where drain contact region 39 is disposed in the sixth region, since both R1 and R2 maintain almost the minimum value, it is advantageous when both R1 and R2 are desired to achieve a low value.

Accordingly, in the plan view, third region A3 may be divided into a fourth region, a fifth region, a sixth region, and a seventh region each of which is equal in area in the first direction, in the plan view, the fourth region, the fifth region, the sixth region, and the seventh region may be arranged in the first direction in stated order from boundary line 90 between first region A1 and third region A3 to boundary line 90 between second region A2 and third region A3, and in the plan view, a center of drain contact region 39 may be located in the sixth region.

As stated above, in semiconductor device 1 according to the embodiment, it is possible to adjust conductive resistance R1 of the first conductive path and conductive resistance R2 of the second conductive path by using the size (area) and installation position of disposing drain contact region 39 after the areas of first region A1 and second region A2 in the plan view are determined. Especially in transistor 20 having the small area, even when second region A2 is expanded to achieve desired ESD tolerance, it is possible to achieve conductive resistance R2 of the second conductive path as a desired high value. For this reason, it is possible to increase a current flowing in the first conductive path and a current flowing in the second conductive path to a desired magnitude.

Although the semiconductor device according to one aspect of the present disclosure is described based on the embodiment, Variations 1 to 4 and the comparative example, the present disclosure is not limited to the embodiment. Forms obtained by various modifications to the embodiment that can be conceived by a person skilled in the art as well as forms realized by combining constituent elements in different embodiments and variations are included in the scope of one or more aspects of the present disclosure, as long as they do not depart from the essence of the present disclosure.

Although only the exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The semiconductor device including the vertical MOS transistor according to the present disclosure is widely applicable as a device that controls a conducting state of a current path.

1. A semiconductor device that is a facedown mountable, chip-size-package type semiconductor device, the semiconductor device comprising:
a semiconductor layer that includes a semiconductor substrate on a back face side and is divided into a first region, a second region, and a third region that do not overlap each other and are not dispersedly disposed in a plan view of the semiconductor device;
a first vertical metal-oxide-semiconductor (MOS) transistor an entirety of which is provided in the first region of the semiconductor layer;
a second vertical MOS transistor an entirety of which is provided in the second region of the semiconductor layer; and
a metal layer that is provided in contact with the back face side of the semiconductor layer,
wherein the semiconductor substrate is a common drain region of the first vertical MOS transistor and the second vertical MOS transistor,
in the plan view, a first source pad and a first gate pad of the first vertical MOS transistor are provided at positions within the first region,
in the plan view, a second source pad and a second gate pad of the second vertical MOS transistor are provided at positions within the second region,
in the plan view, a drain pad that is connected to the common drain region is provided at a position within the third region,
in the plan view, the first region and the second region are disposed with the third region interposed therebetween,
in the plan view, the third region is adjacent to the first region and the second region, and
in the plan view, an area of the first region is larger than an area of the second region.

2. The semiconductor device according to claim 1,
wherein in the plan view, a boundary length between the first region and the third region is greater than a boundary length between the second region and the third region.

3. The semiconductor device according to claim 2,
wherein in the plan view, the semiconductor layer is rectangular in shape, and
in the plan view, the first region is disposed to have an outer periphery of the first region partially coinciding with four sides of the semiconductor layer.

4. The semiconductor device according to claim 2,
wherein in the plan view, the second gate pad is disposed closest to a corner portion defined by, among outer peripheral sides of the second region, two outer peripheral sides that are not adjacent to the third region.

5. The semiconductor device according to claim 2,
wherein in the plan view, the second gate pad is disposed closest to a corner portion farthest from the drain pad among corner portions defined by outer peripheral sides of the second region.

6. The semiconductor device according to claim 1,
wherein the semiconductor substrate is of a first conductivity type and includes an impurity having a first concentration,
the semiconductor layer includes a low-concentration impurity layer of the first conductivity type, the low-concentration impurity layer being provided on the semiconductor substrate and including an impurity having a second concentration lower than the first concentration,
in the plan view, a drain lead-out region of the first conductivity type is provided in the third region, the drain lead-out region being connected to the common drain region and including an impurity having a concentration higher than the first concentration,
in the plan view, a frontside drain electrode is provided at a position within the third region, the frontside drain electrode being in contact with a surface of the semiconductor layer and connected to the drain lead-out region, and
in the plan view, an area of a drain contact region in which the frontside drain electrode and the drain lead-out region are connected is at most ¼ of an area of the third region.

7. The semiconductor device according to claim 6,
wherein in the plan view, the third region is rectangular in shape,
a maximum width of the drain contact region in a first direction that is parallel to a shorter side of the third region is less than a maximum width of the drain contact region in a second direction that is orthogonal to the first direction and parallel to a longer side of the third region in the plan view, and
in the plan view, the maximum width of the drain contact region in the first direction is at most ¼ of a length of the shorter side of the third region.

8. The semiconductor device according to claim 7,
wherein in the plan view, the third region is divided into a fourth region, a fifth region, a sixth region, and a seventh region that are equal in area in the first direction,
in the plan view, the fourth region, the fifth region, the sixth region, and the seventh region are arranged in the first direction in stated order from a boundary line between the first region and the third region to a boundary line between the second region and the third region, and
in the plan view, a center of the drain contact region is located in the fifth region.

9. The semiconductor device according to claim 7,
wherein in the plan view, the third region is divided into a fourth region, a fifth region, a sixth region, and a seventh region each of which is equal in area in the first direction,
in the plan view, the fourth region, the fifth region, the sixth region, and the seventh region are arranged in the first direction in stated order from a boundary line between the first region and the third region to a boundary line between the second region and the third region, and
in the plan view, a center of the drain contact region is located in the fourth region.

10. The semiconductor device according to claim 7,
wherein in the plan view, the third region is divided into a fourth region, a fifth region, a sixth region, and a seventh region each of which is equal in area in the first direction,
in the plan view, the fourth region, the fifth region, the sixth region, and the seventh region are arranged in the first direction in stated order from a boundary line between the first region and the third region to a boundary line between the second region and the third region, and
in the plan view, a center of the drain contact region is located in the sixth region.
